(19) United States
(12) Patent Application Publication
(10) Pub. No.: US 2009/0168482 A1
(43) Pub. Date: Jul. 2, 2009

(54) THREE-DIMENSIONAL MEMORY DEVICE

(75) Inventors: Ki-Tae PARK, Seongnam-si (KR); Yeong-Taek LEE, Seoul (KR); Doo-Gon KIM, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/343,630

(22) Filed: Dec. 24, 2008

(30) Foreign Application Priority Data
Dec. 28, 2007 (KR) 10-2007-0140496

(51) Int. Cl. G11C 17/08; G11C 5/02

(52) U.S. Cl. 365/51; 365/103

(57) ABSTRACT

A three-dimensional memory device includes a base layer having a memory array and peripheral circuits formed on a bulk silicon substrate, and N circuit layers each having a memory array formed on a silicon-on-insulator (SOI) substrate. The N circuit layers are vertically stacked one on top of the other on the base layer and the uppermost Nth circuit layer additionally includes passive elements

### CROSS-REFERENCE TO RELATED APPLICATIONS

This U.S. non-provisional patent application claims priority under 35 U.S.C. §119 to Korean Patent Application No. 10-2007-0140496 filed on Dec. 28, 2007, the subject matter of which is hereby incorporated by reference.

### BACKGROUND

The present invention relates generally to a three-dimensional memory device and related programming methods.

The development and evolution of semiconductor memory devices are characterized by constant efforts to reduce the per unit area of memory cells and related peripheral circuitry. That is, each successive generation of semiconductor memory devices has greater memory cell integration density than the preceding generation. The three dimension arrangement of elements within a memory cell array is one technique used to increase memory cell integration density. Examples of three-dimensional array structures or “3-dimensional memory devices” are disclosed in U.S. Pat. No. 5,835,396 issued Nov. 10, 1998 and entitled, “THREE-DIMENSIONAL READ-ONLY MEMORY”; U.S. Pat. No. 6,034,882 issued Mar. 7, 2000 and entitled, “VERTICALLY STACKED FIELD PROGRAMMABLE NONVOLATILE MEMORY AND METHOD OF FABRICATION”; and U.S. Pat. No. 7,002,825 issued Feb. 21, 2006 and entitled, “WORD LINE ARRANGEMENT HAVING SEGMENTED WORD LINES”. The collective subject matter of these references is hereby incorporated by reference.

In one aspect, 3-dimensional memory devices include memory cell arrays formed at a plurality of different semiconductor material layers. This plurality of semiconductor material layers may be viewed as a vertical (Z-direction) stack of planar (X-Y directions) layers. This, the different semiconductor layers may be understood as planar layers fabricated at different heights within a vertical stack of layers ascending from a base layer. As is well understood in the art, the base layer is most commonly implemented as a bulk silicon substrate. Various conventionally understood fabrication processes (e.g., deposition, epitaxial growth, photolithography, etching, implantation, cleaning. etc.) are used to (largely) sequentially fabricate the plurality of semiconductor layers on the silicon substrate.

### SUMMARY OF THE INVENTION

Embodiments of the invention are directed to a 3-dimensional memory device fabricated using a relatively more simple fabrication process. Embodiments of the invention are also directed to the design and fabrication of a 3-dimensional memory device having a reduced overall size.

In one embodiment, the invention provides a three-dimensional memory device comprising; a base layer comprising a memory array and peripheral circuits formed on a bulk silicon substrate, and N circuit layers, where N is a positive integer, each comprising a memory array formed on a silicon-on-insulator (SOI) substrate, wherein the N circuit layers are vertically stacked one on top of the other on the base layer and the uppermost Nth circuit layer additionally comprises passive elements.

In another embodiment, the invention provides a three-dimensional memory device comprising; a base layer comprising a memory array and passive circuits formed on a bulk silicon substrate, and N circuit layers, where N is a positive integer, each comprising a memory array formed on a silicon-on-insulator (SOI) substrate, wherein the N circuit layers are vertically stacked one on top of the other on the base layer and the uppermost Nth circuit layer additionally comprises peripheral circuits.

In another embodiment, the invention provides a three-dimensional memory device comprising; a base layer comprising a memory array, first peripheral circuits, and first passive elements formed on a bulk silicon substrate, and N circuit layers, where N is a positive integer, each comprising a memory array formed on a silicon-on-insulator (SOI) substrate, wherein the N circuit layers are vertically stacked one on top of the other on the base layer and the uppermost Nth circuit layer additionally comprises second peripheral circuits and second passive elements.

### BRIEF DESCRIPTION OF THE FIGURES

FIG. 1 illustrates an embodiment of a 3-dimensional memory device according to an embodiment of the invention;

FIG. 2 further illustrates circuitry related to the 3-dimensional memory device of FIG. 1;

FIG. 3 further illustrates a cross-sectional structure of the 3-dimensional memory device shown in FIG. 2;

FIG. 4 illustrates another embodiment of a 3-dimensional memory device according to an embodiment of the invention;

FIG. 5 further illustrates circuitry related to the 3-dimensional memory device of FIG. 4;

FIG. 6 further illustrates a cross-sectional structure of the 3-dimensional memory device shown in FIG. 5;

FIG. 7 illustrates another embodiment of a 3-dimensional memory device according to an embodiment of the invention;

FIG. 8 further illustrates circuitry related to the 3-dimensional memory device of FIG. 7;

FIG. 9 further illustrates a cross-sectional structure of the 3-dimensional memory device shown in FIG. 8;

FIG. 10 is a circuit diagram illustrating another embodiment of a 3-dimensional memory device according to an embodiment of the invention; and

FIG. 11 is a block diagram of a memory system incorporating one or more 3-dimensional memory device(s) according to an embodiment of the invention.

### DESCRIPTION OF EMBODIMENTS

Certain embodiments of the invention will now be described in some additional detail with reference to the accompanying drawings. The present invention may, however, be embodied in different forms and should not be constructed as being limited to only the illustrated embodiments. Rather, the embodiments are presented as teaching examples of the making and use of the invention. Throughout the written description and drawings, like reference numerals are used to indicate like or similar elements.

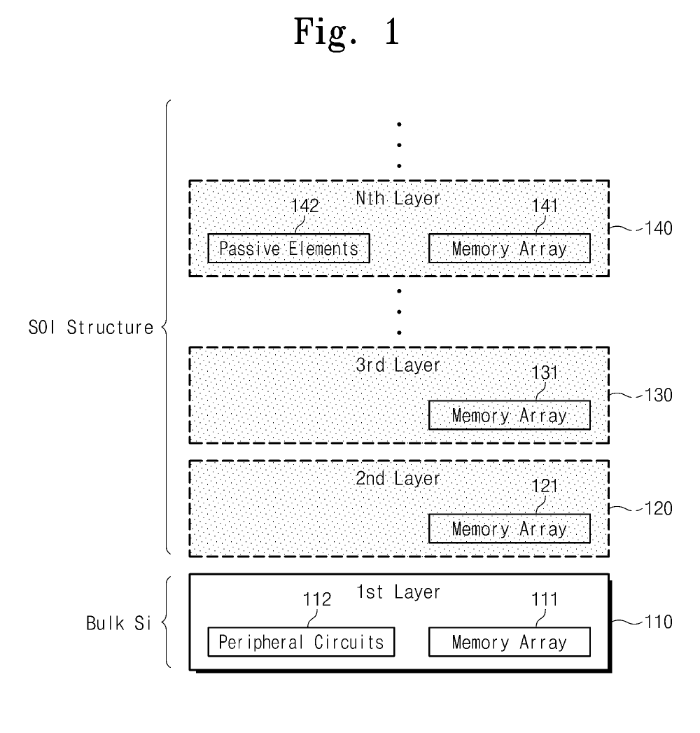

FIG. (FIG.) 1 illustrates a 3-dimensional memory device according to an embodiment of the invention. Referring to FIG. 1, the 3-dimensional memory device comprises of a base layer 110 formed from a bulk silicon substrate (Bulk Si), and a plurality of different semiconductor layers formed on the bulk silicon substrate. Since each semiconductor layer in the plurality of different semiconductor layers includes circuitry (e.g., memory cell array circuitry and/or associated peripheral circuitry), the various semiconductor layers in the illustrated embodiments will be referred to as circuit layers 120, 130, and 140. Base layer 110 may also be termed a circuit layer, since it may also incorporate such circuitry. However, circuit layer 120, 130, and 140 are said to be “vertically stacked” on base layer 110. This description ascribes a conventionally understood geometry to the arrangement of circuit layers in embodiments of the invention. However, this geometry is merely a convenient reference describing the structure wherein one or more circuit layers (e.g., having a silicon-on-insulator (SOI) structure) are stacked mounted one on top of the other on the base layer. Those skilled in the art understand the mechanical and electrical fabrication techniques used to vertically stack circuit layers to thereby reduce the overall area footprint of the resulting 3-dimensional memory device.

In the illustrated embodiments, it is assumed that each circuit layer is fabricated using conventionally understood processes to form a silicon-on-insulator (SOI) structure. As is also conventionally understood, the SOI structure is generally fabricated using a single crystalline silicon layer formed on an underlying insulation film. Thus, in the contemplated SOI structure, the device elements in each circuit layer are generally isolated above and below by insulation or dielectric materials (e.g., a silicon oxide films), and not directly connected to the bulk silicon substrate. This insulated structure reduces inter-circuit-layer parasitic capacitance and crosstalk between device elements, thereby allowing the overall memory device to operate at a higher frequency, improved current gain, better resistance to high voltages, and more efficient power consumption, etc. Such benefits associated with SOI structures notwithstanding, it is also possible to implement the plurality of circuit layers using other fabrication techniques.

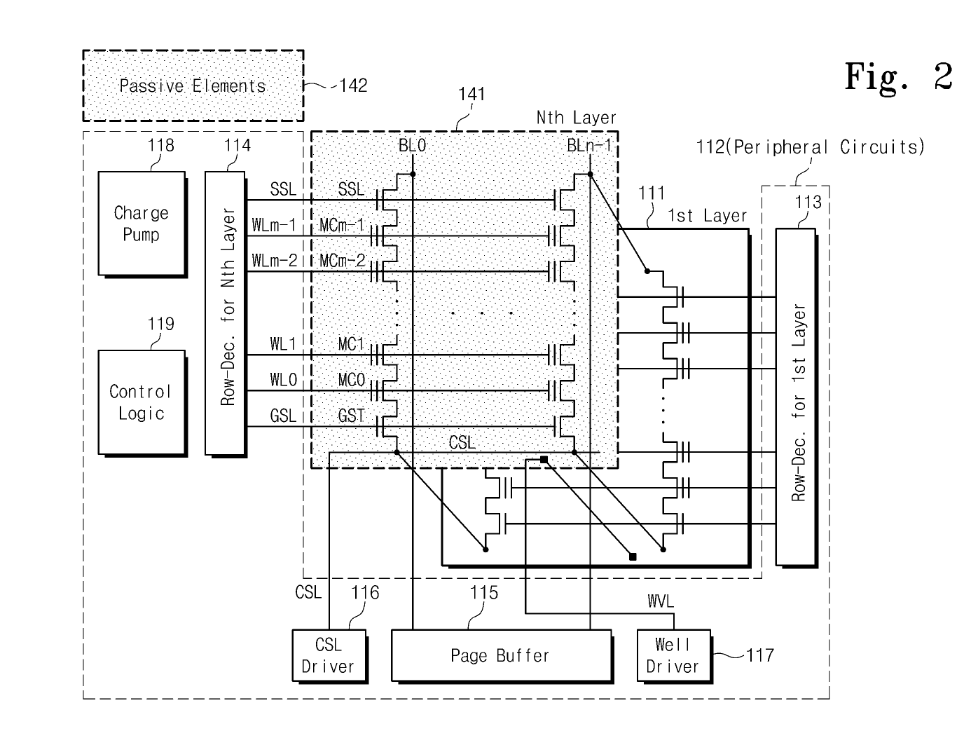

In the illustrated embodiment of FIG. 1, each of circuit layers 110, 120, 130, and 140 includes at least one memory cell array 111, 121, 131, and 141, respectively. Base layer 110 (or first circuit layer 110) also includes conventional peripheral circuits 112 necessary to the operation of memory arrays 111 through 141. Those skilled in the art will understand that a great number and type of “peripheral circuits” may necessarily be incorporated within one or more of the circuit layers forming a 3-dimension memory device. The operative nature and arrangement of such peripheral circuits will vary with the nature of the memory arrays in the 3-dimensional memory device (volatile, non-volatile or both), as well as many other design factors. Therefore, the exact nature and layout of such conventionally understood peripheral circuits 112 will not be further described in the context of the embodiment illustrated in FIG. 1. In the description that follows, however, some convenient examples of peripheral circuits will be given. (See, FIG. 2). However, these examples are not meant to be complete or exhaustive, merely exemplary.

Thus, the embodiment illustrated in FIG. 1 comprises “N” circuit layers, 110 through 140. In addition to memory array 141, the top or Nth circuit layer 140 also comprises certain circuitry hereafter generally designated as “passive elements 142”. Passive elements 142 may include decoupling and other capacitors, various resistors, etc., used in relation to peripheral circuits 112 and/or one or more of memory arrays 111 through 141.

Although not illustrated in the embodiment of FIG. 1, various input/output (I/O) structures (e.g., I/O pads, lands, connective vias, wiring, etc.) will also be conventionally incorporated within circuit layers 110 through 140. That is, data, address, and/or control signals will be communicated to the various memory array, peripheral circuit and passive elements within the 3-dimensional memory device using conventionally understood techniques not specifically shown in the illustrated embodiments.

Thus, in the embodiment of FIG. 1, the 3-dimensional memory device comprises circuit layers 110 through 140, each respectively including a memory array 111 through 141. The base layer 110 further includes peripheral circuits 112 and the Nth layer 140 includes passive elements 142. Base layer 110 in particular may be fabricated as a conventional 2-dimensional memory device. Base layer 110 may also be provided as a memory controller or interface device associated with vertically stacked circuit layers. The memory arrays in the various circuit layers need not be identical in operative nature. For example, memory array 111 in FIG. 1 might be a NAND flash array and base layer 110 of the 3-dimensional memory device may be fabricated as a conventional NAND flash memory device, whereas one or more of memory arrays 121 through 141 might be DRAM or SRAM.

FIG. 2 further illustrates the 3-dimensional memory device shown in FIG. 1. Referring to FIG. 2, circuit blocks 111 and 113 through 119 inclusive are included in base first layer 110. Blocks 141 and 142 are included in the Nth layer 140. Blocks 113 through 119 are exemplary circuits included within peripheral circuits 112. Blocks 111 and 141 are assumed to be respective memory cells arrays of NAND flash memory cells. Further, in illustrated 3-dimensional memory device, including circuit layers 110 and 140, is configured with (e.g.,) share bit lines BL0 through BLn-1, a common source line CSL, a well voltage line WVL, and a page buffer 115.

As illustrated in FIG. 2, base layer 110 comprises memory array 111, row decoders 113 and 114, a page buffer 115, a common source line driver 116, a well driver 117, a charge pump 118, and a control logic circuit 119. Here, memory array 111, row decoder 113, page buffer 115, common source driver 116, well driver 117, charge pump 118, and control logic circuit 119 are assumed to be conventional in design and operation in relation to a NAND flash memory device.

Row decoder 114 physically disposed in base layer 110 may nonetheless be used in a conventional manner to drive memory array 141 disposed in the Nth circuit layer 140.

The Nth (or the top circuit layer in this particular embodiment) circuit layer 140 comprises memory array 141 and passive elements 142. Passive elements, such as decoupling capacitors and impedance matching resistors, for example, are associated with one or more of the peripheral circuits 112, or one or more signal lines extending from peripheral circuits 112 to one ore more the upper circuit layers.

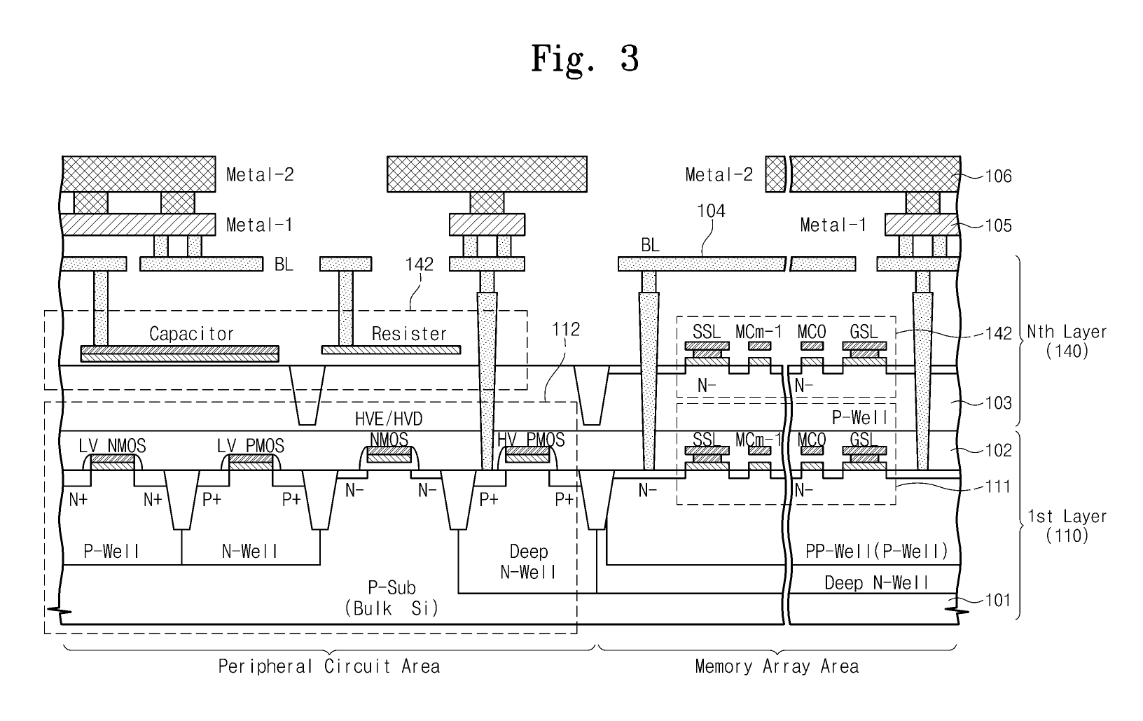

FIG. 3 further illustrates a cross-sectional structure of the 3-dimensional memory device shown in FIG. 2. Referring to FIG. 3, base layer 110 including memory array 111 and Nth layer 140 including memory array 141 are shown. In other embodiments of the invention, one or more intervening circuit layers may be present between base layer 110 and Nth layer 140. Respective memory arrays 111 and 141 are disposed in vertically aligned the memory array regions of each circuit layer, memory array 111 being formed on a bulk silicon substrate 101 of base layer 110, and memory array 141 being formed on a single-crystalline silicon substrate 103 of Nth circuit layer 140. The single-crystalline silicon substrate 103 may be formed on an insulation film (e.g., oxide film) 102 to yield Nth layer 140 in the form of an SOI structure.

Memory arrays 111 and 141 according to the illustrated embodiment of the invention share a bit line (BL) 104. Bit line 104 may be made of tungsten (W) or some other electrically conductive material. First and second metal layers 105 and 106 may be made from aluminum (Al) or some other electrically conductive material.

Peripheral circuits 112 disposed on base layer 110 are further illustrated as possibly including low-voltage N-type metal-oxide-semiconductor (NMOS) transistors, low-voltage P-type metal-oxide-semiconductor (PMOS) transistors, high-voltage enhancement/depletion (HVE/HVD) NMOS transistors, and high-voltage PMOS transistors. But these circuit elements are merely exemplary of a range of elements that may be used to implement specific peripheral circuits in the peripheral circuit regions of base layer 110 and Nth circuit layer 140. Nth circuit layer 140 also includes passive elements 142.

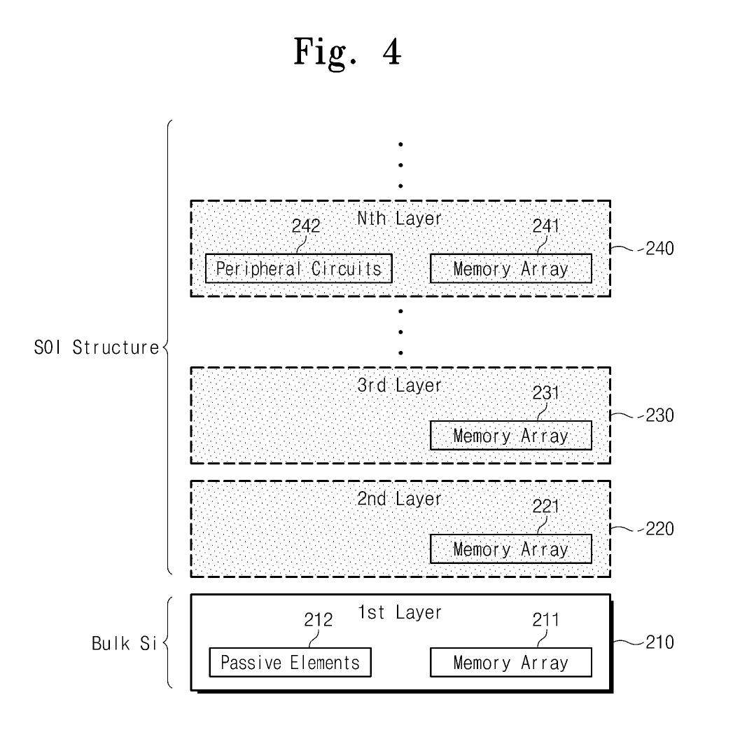

FIG. 4 illustrates another 3-dimensional memory device according to an embodiment of the invention. Memory circuits 211 through 241, peripheral circuits 242, and passive elements 212 are analogous to similar circuits described in relation to the embodiment of FIG. 1, but are otherwise disposed among the circuits layers 210 through 240. In particular, peripheral circuits 242 are disposed on the Nth circuit layer 240 and passive elements 212 are disposed on base layer 210.

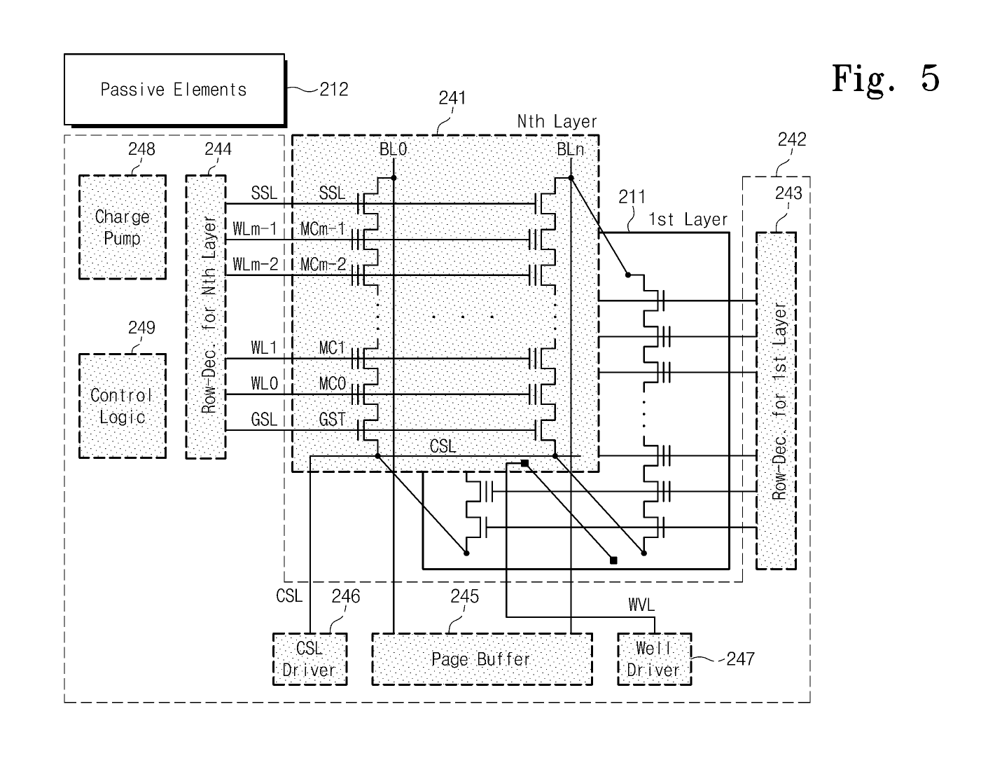

FIG. 5 further illustrates the 3-dimensional memory device shown in FIG. 4 with base layer 210 including memory array 211 and the passive elements 212, and the Nth circuit layer 240 including memory array 241 and peripheral circuits 242. Peripheral circuits 242 include (e.g.,) row decoders 243 and 244, page buffer 245, common source line driver 246, well voltage driver 247, charge pump 248, and control logic circuit 249. In the illustrated 3-dimensional memory device, circuit layers 210 and 240 are configured to share bit lines BL0 through BLn-1, common source line CSL, well voltage line WVL, and page buffer 245.

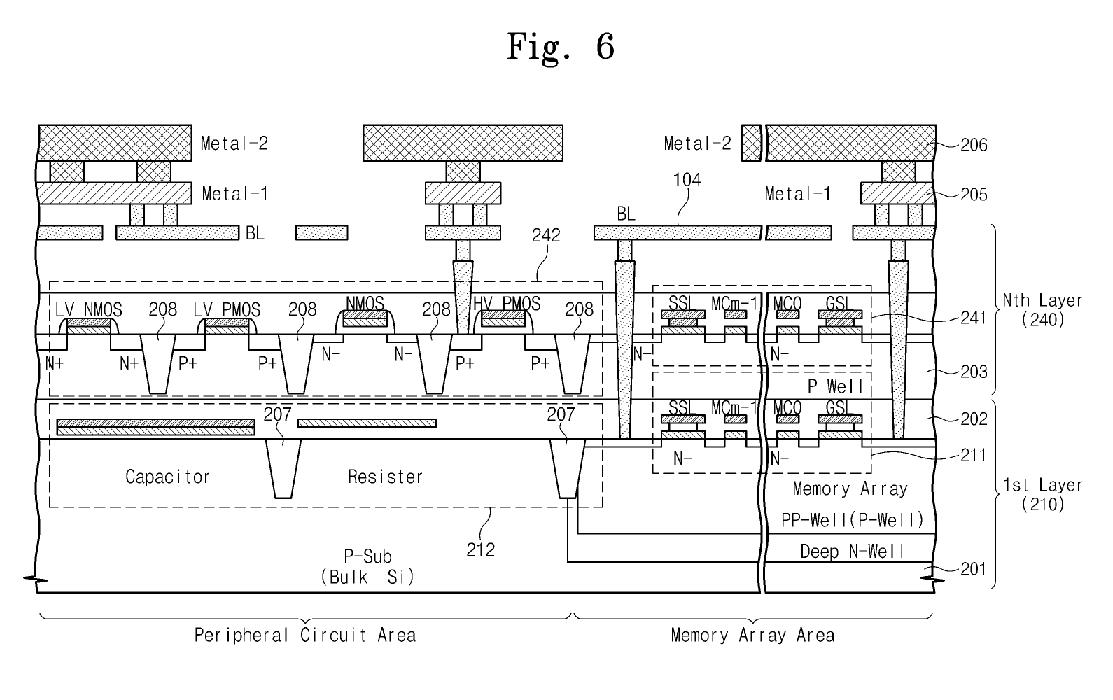

FIG. 6 further illustrates a cross-sectional structure of the 3-dimensional memory device shown in FIG. 5. Referring to FIG. 6, circuit layers 210 and 240 include memory arrays 211 and 241, respectively. Memory array 211 is formed on a bulk silicon substrate 201 and memory array 241 is formed on a single-crystalline silicon substrate 203. The single-crystalline silicon substrate 203 is fabricated on an insulation film (e.g., oxide film) 202, thereby forming an SOI structure.

Passive elements 212 are included in base layer 210 and are formed on bulk silicon substrate 202. Passive circuits 212 again include capacitors and resistors associated with various peripheral circuits 242. Passive elements 212 are electrically separated by device isolation films 207 which may be formed using shallow trench isolation techniques.

Peripheral circuits 242 are included in the Nth circuit layer 210 on single-crystalline silicon substrate 203. As described above, peripheral circuits 242 may include a number of different (but conventionally understood) circuits adapted for use in conjunction with a prescribed type of memory array. Such circuits are most commonly formed by an operative collection of low-voltage NMOS transistors, low-voltage PMOS transistors, high-voltage enhancement/depletion MOS transistors, and high-voltage PMOS transistors. As shown in relation to the illustrated elements forming peripheral circuits 242, certain device isolation films 208, and device isolation layer 202 (e.g., formed from silicon oxide) may be used to electrically separate circuit elements. Device isolation films 208 may be fabricated using shallow trench isolation techniques. Adequate isolation characteristics may be obtained even though device isolation films 208 formed in single-crystalline silicon substrate 203 are relatively thinner than device isolation films 207. This efficient provision of electrical isolation by device isolation films 208 enables peripheral circuits 242 to be integrated with a relatively smaller size on single-crystalline silicon substrate 203 than peripheral circuits 112 formed in bulk silicon substrate 101 of FIG. 3. As a result, it is possible to shrink the vertical profile of the 3-dimensional memory device of FIG. 6 over the 3-dimensional memory device of FIG. 3. Generally, if the device isolation films are formed by shallow trench isolation, the dimensions of peripheral circuits 242 shown in FIG. 6 can be reduced by about 10% over the dimensions of peripheral circuits 212 shown in FIG. 3.

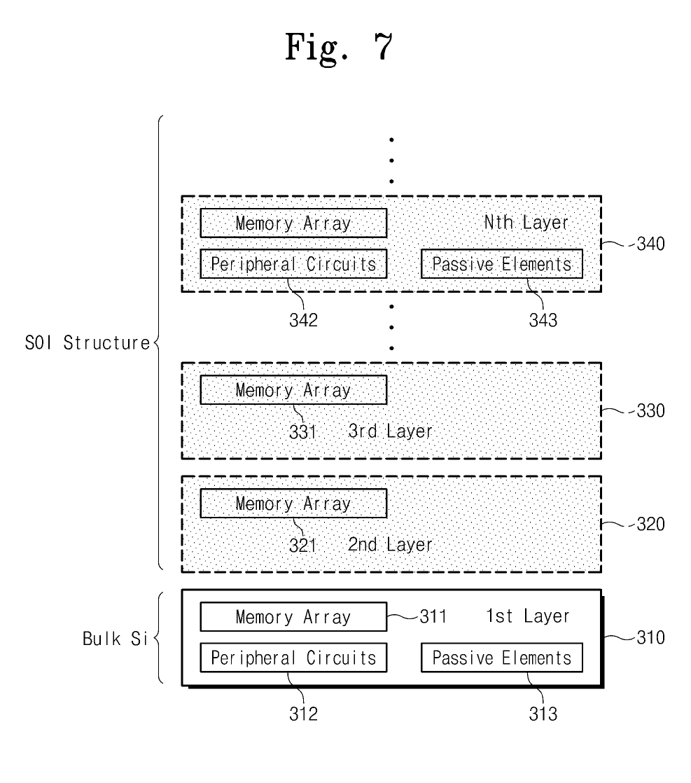

FIG. 7 illustrates a 3-dimensional memory device according to another embodiment of the invention. Referring to FIG. 7, a base layer 310 includes first peripheral circuits 312 and first passive elements 313, and an Nth circuit layer 340 includes second peripheral circuits 342 and second passive elements 343. Circuit layers 310, 320, 330, and 340 include memory arrays 311, 321, 331, and 341, respectively. Base (or first circuit) layer 310 is formed on the bulk silicon substrate while the remaining circuit layers 320 through 340 are formed as SOI structures.

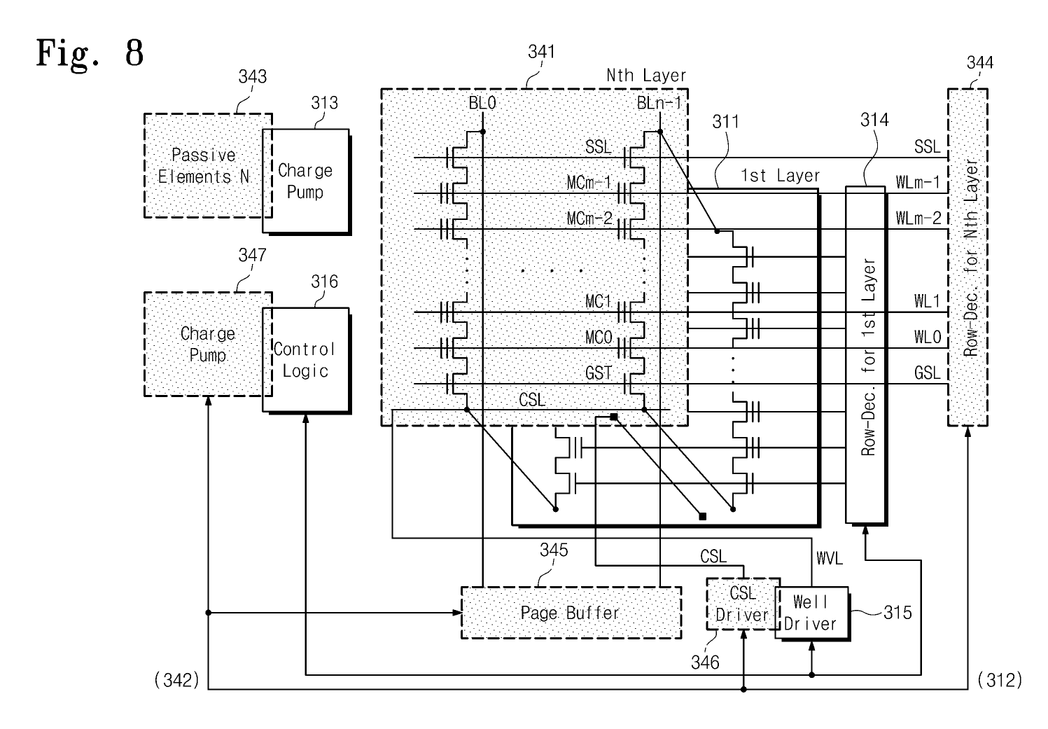

FIG. 8 further illustrates the 3-dimensional memory device shown in FIG. 7. Referring to FIG. 8, circuit blocks indicated by solid lines are included in base layer 310 and the circuit blocks indicated by dotted lines are included in the Nth circuit layer 340. Base layer 310 includes first memory array 311, first peripheral circuits 312, and first passive elements 313. First peripheral circuits 312 include, as examples, first row decoder 314, well voltage driver 315, and control logic circuit 316. Nth circuit layer 340 includes second memory array 341, second peripheral circuits 342, and second passive elements 343. Second peripheral circuits 342 include, as examples, second row decoder 344, page buffer 345, common source line driver 346, and charge pump 347. In the illustrated 3-dimensional memory device, circuit layers 310 and 340 are configured to share bit lines BL0 through BLn-1, common source line CSL, well voltage line WVL, and page buffer 345.

Especially in the 3-dimensional memory device illustrated in FIG. 8, first and second peripheral circuits 312 and 342 may be overlapped one with another (i.e., at least partially aligned in a vertical direction down through the stack of circuit layers). For instance, as illustrated in FIG. 8, first and second row decoders, 314 and 344, well voltage driver 315 and common source line driver 346, and control logic circuit 316 and charge pump 347 overlapped each other, respectively. By overlapping some or all of peripheral circuits 312 and 342, the area occupied by peripheral circuits 312 and 342 may be reduced, as compared with the former illustrated embodiments.

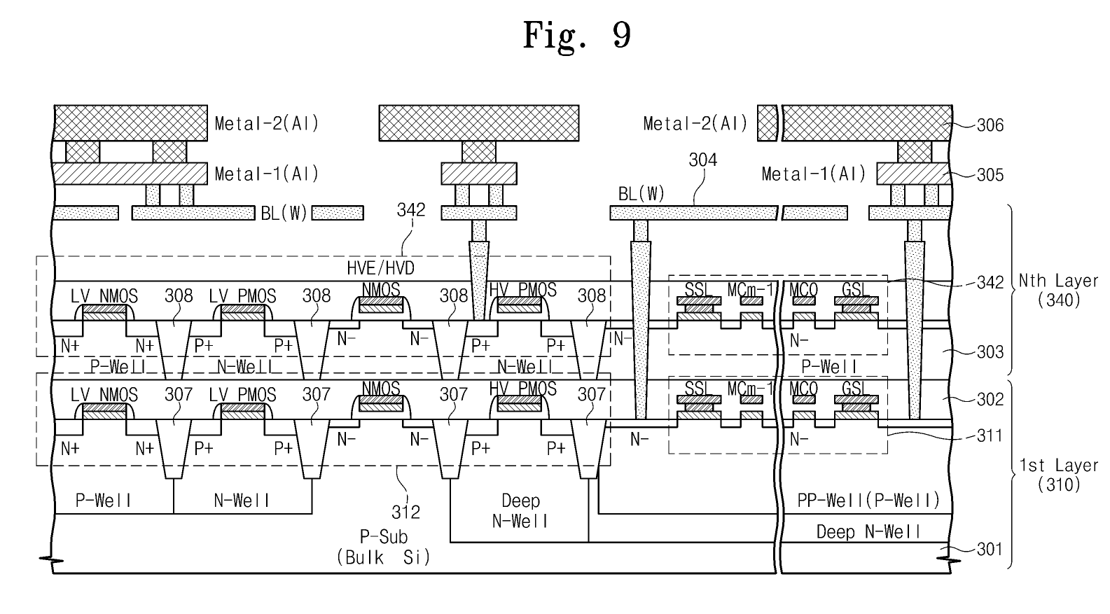

FIG. 9 further illustrates a cross-sectional structure of the 3-dimensional memory device shown in FIG. 8. Referring to FIG. 9, base layer 310 and Nth circuit layer 340 includes memory arrays 311 and 341, respectively. Memory array 311 is formed on a bulk silicon substrate 301 and the memory array 341 is formed on a single-crystalline silicon substrate 303. The single-crystalline silicon substrate 303 is formed on an insulation film (e.g., oxide film) 302.

In the 3-dimensional memory device shown in FIG. 9, first and second peripheral circuits 312 and 342 are disposed in overlap with one another. First peripheral circuits 312 are included in base layer 310 formed on bulk silicon substrate 301. Here again, first peripheral circuits 312 (and second peripheral circuits 342) are circuits formed by operative combinations of low-voltage NMOS transistors, low-voltage PMOS transistors, high-voltage enhancement/depletion MOS transistors, and high-voltage PMOS transistors, etc.

Second peripheral circuits 342 are included in the Nth circuit layer 340 on single-crystalline silicon substrate 303. Although not shown, first passive elements 313 are formed on bulk silicon substrate 301 and second passive elements 343 are formed on single-crystalline silicon substrate 303.

The 3-dimensional memory device shown in FIG. 8 is formed with a structure wherein the plurality of circuit layers may share at least one bit line. But it is unnecessary for all of the circuit layers in the 3-dimensional memory device to share a particular bit line (or a common set of bit lines).

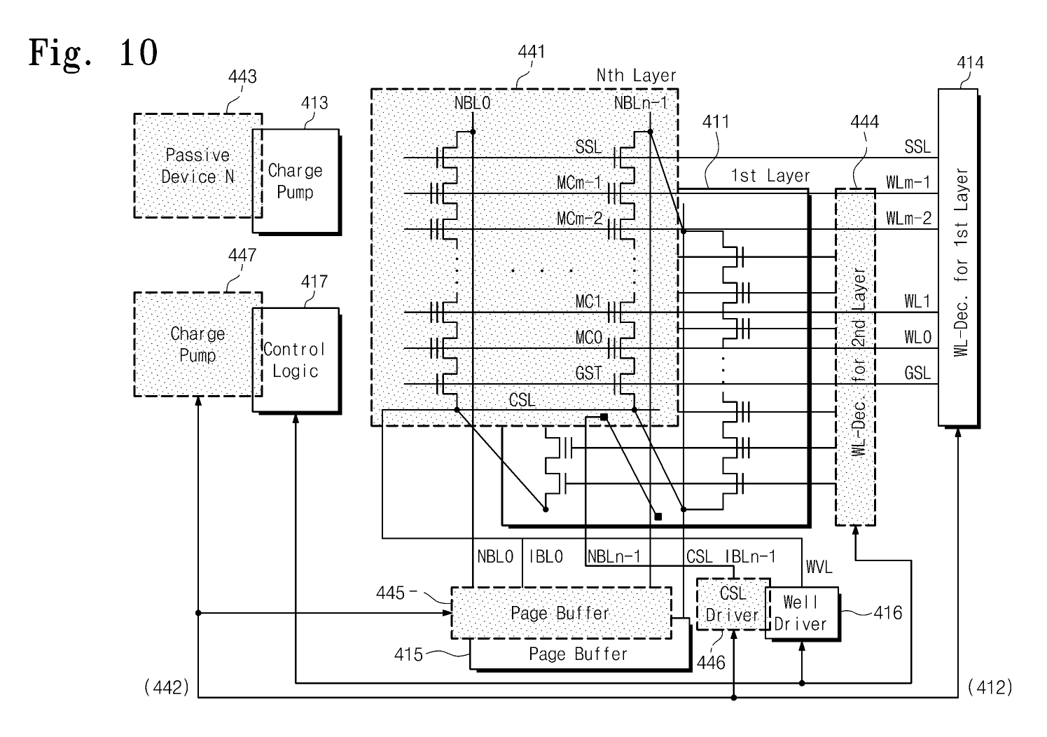

For example, FIG. 10 is a circuit diagram illustrating yet another 3-dimensional memory device according to an embodiment of the invention. Referring to FIG. 10, respective circuit layers do not share a bit line in the 3-dimensional memory device. As illustrated in FIG. 10, first bit lines 1BL0 through 1BLn-1 are connected to a first page buffer 415 and second bit lines NBL0 through NBLn-1 are connected to a second page buffer 445. First page buffer 415 is included in base layer and second page buffer 445 is included in the Nth circuit layer. Other circuit blocks are arranged as previously described in relation to the embodiment shown in FIG. 8.

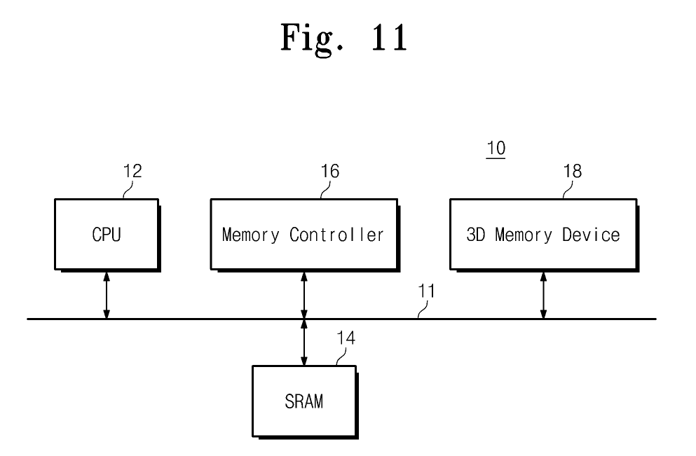

FIG. 11 is a block diagram of a memory system incorporating at least one 3-dimensional memory device according to an embodiment of the invention. Referring to FIG. 11, a memory system 10 is organized from a central processing unit (CPU) 12, a static RAM (SRAM) 14, a memory controller 16, and a 3-dimensional memory device 18, all of which are electrically connected via a bus 11. The 3-dimensional memory device 18 may be configured substantially as same as that shown in FIG. 1, 4, 7 or 10. In the 3-dimensional memory device 18, N-bit data (N is a positive integer) processed or to be processed by the CPU 12 may be stored through the memory controller 16.

Although not shown in FIG. 11, the computing system may be further equipped with an application chipset, a camera image processor (e.g., complementary metal-oxide-semiconductor (CMOS) image sensor; i.e., CIS), a mobile DRAM, etc. The memory controller 16 and the 3-dimensional memory device 18 may be even embedded in a solid state drive or disk (SSD).

The 3-dimensional memory device 18 and/or the memory controller 16 can be mounted on the memory system 10 by means of various types of packages. For instance, the 3-dimensional memory device 18 and/or the memory controller 16 may be placed thereon by any package type, e.g., Package-on-Package (PoP), Ball Grid Arrays (BGAs), Chip Scale Packages (CSPs), Plastic Leaded Chip Carrier (PLCC), Plastic Dual In-line Package (PDIP), Die in Waffle Pack, Die in Wafer Form, Chip-On-Board (COB), CERamic Dual In-line Package (CERDIP), Plastic Metric Quad Flat Pack (MQFP), Thin Quad Flat Pack (TQFP), Small Outline (SOIC), Shrink Small Outline Package (SSOP), Thin Small Outline (TSOP), Thin Quad Flat Pack (TQFP), System In Package (SIP), Multi-Chip Package (MCP), Wafer-level Fabricated Package (WFP), Wafer-level Processed Stack Package (WSP), or Wafer-level Processed Package (WSP).

The above-disclosed subject matter is to be considered illustrative, and not restrictive, and the appended claims are intended to cover all such modifications, enhancements, and other embodiments, which fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A three-dimensional memory device comprising:
a base layer comprising a memory array and peripheral circuits formed on a bulk silicon substrate; and
N circuit layers, where N is a positive integer, each comprising a memory array formed on a silicon-on-insulator (SOI) substrate,
wherein the N circuit layers are vertically stacked one on top of the other on the base layer and the uppermost Nth circuit layer additionally comprises passive elements.

2. The three-dimensional memory device of claim 1, wherein the memory array of the base layer and the respective memory arrays of the N circuit layers are driven by the peripheral circuits.

3. The three-dimensional memory device of claim 1, wherein the memory array of the base layer and the respective memory arrays of the N circuit layers are respectively configured to share at least one bit line.

4. The three-dimensional memory device of claim 1, wherein the passive elements comprise decoupling capacitors and resistors associated with signal lines extending from the peripheral circuits.

5. The three-dimensional memory device of claim 1, wherein the Nth layer further comprises input/output pads.

6. The three-dimensional memory device of claim 1, wherein each one of the N circuit layers comprises input/output pads.

7. A three-dimensional memory device comprising:
a base layer comprising a memory array and passive circuits formed on a bulk silicon substrate; and
N circuit layers, where N is a positive integer, each comprising a memory array formed on a silicon-on-insulator (SOI) substrate,
wherein the N circuit layers are vertically stacked one on top of the other on the base layer and the uppermost Nth circuit layer additionally comprises peripheral circuits.

8. The three-dimensional memory device of claim 7, wherein the memory array of the base layer and the respective memory arrays of the N circuit layers are driven by the peripheral circuits.

9. The three-dimensional memory device of claim 7, wherein the memory array of the base layer and the respective memory arrays of the N circuit layers are respectively configured to share at least one bit line.

10. The three-dimensional memory device of claim 7, wherein the passive elements comprise decoupling capacitors and resistors associated with signal lines extending from the peripheral circuits.

11. The three-dimensional memory device of claim 7, wherein the base layer further comprises input/output pads.

12. The three-dimensional memory device of claim 7, wherein each one of the N circuit layers comprises input/output pads.

13. A three-dimensional memory device comprising:
a base layer comprising a memory array, first peripheral circuits, and first passive elements formed on a bulk silicon substrate; and
N circuit layers, where N is a positive integer, each comprising a memory array formed on a silicon-on-insulator (SOI) substrate,
wherein the N circuit layers are vertically stacked one on top of the other on the base layer and the uppermost Nth circuit layer additionally comprises second peripheral circuits and second passive elements.

14. The three-dimensional memory device of claim 13, wherein the memory array of the base layer and the respective memory arrays of the N circuit layers are driven by at least one of the first and second peripheral circuits.

15. The three-dimensional memory device of claim 13, wherein the memory array of the base layer and the respective memory arrays of the N circuit layers are respectively configured to share at least one bit line.

16. The three-dimensional memory device of claim 13, wherein the memory array of the base layer is associated with a first set of bit lines and at least one of the respective memory arrays of the N circuit layers is associated with a second set of bit lines different from the first set of bit lines.

17. The three-dimensional memory device of claim 13, wherein the first and second passive elements comprise decoupling capacitors and resistors associated with signal lines extending from at least one of the first and second peripheral circuits.

18. The three-dimensional memory device of claim 12, wherein the first and second peripheral circuits are disposed overlapping one another.

19. The three-dimensional memory device of claim 18, wherein the first and second passive elements are disposed overlapping one another.
